(19) United States
(12) Patent Application Publication
(10) Pub. No.: US 2025/0271905 A1
(43) Pub. Date: Aug. 28, 2025

(54) DISPLAY APPARATUS AND METHOD OF MANUFACTURING THE SAME

(71) Applicant: Samsung Display Co., Ltd., Yongin-Si (KR)

(72) Inventors: Dasong Lee, Yongin-si (KR); Wonseok Kim, Yongin-si (KR); Kangwoo Lee, Yongin-si (KR); Hyunjung Lee, Yongin-si (KR)

(21) Appl. No.: 18/961,450

(22) Filed: Nov. 27, 2024

(30) Foreign Application Priority Data
Feb. 22, 2024 (KR) 10-2024-0026039

(51) Int. Cl. G06F 1/16

(52) U.S. Cl. CPC G06F 1/1656; G06F 1/1616; G06F 1/1624

(57) ABSTRACT

Provided are a display apparatus and a method of manufacturing the display apparatus, the display apparatus including a display panel including a first area, a second area, a folding area between the first area and the second area, and a sliding area across the first area from the folding area, a support plate supporting a lower surface of the display panel and including a first plate portion overlapping the first area, a second plate portion overlapping the second area, a first grid pattern portion overlapping the folding area, and a second grid pattern portion overlapping the sliding area, a main adhesive layer between the display panel and the support plate, and an auxiliary adhesive layer between the main adhesive layer and the support plate and overlapping a portion of the support plate.

### CROSS-REFERENCE TO RELATED APPLICATION

This application is based on and claims priority, under 35 U.S.C. § 119, to Korean Patent Application No. 10-2024-0026039 filed on Feb. 22, 2024 in the Korean Intellectual Property Office, the disclosure of which is incorporated by reference herein in its entirety.

### BACKGROUND

### 1. Field

The embodiments of the disclosure relate to a display apparatus, and more particularly, to a display apparatus with improved reliability and a method of manufacturing the same.

### 2. Description of the Related Art

Much research and development on flexible display apparatuses have been actively underway. A display screen of the flexible display apparatus may be folded, bent, slid, etc. to extend or reduce the display screen, making it a great contribution to reducing the volume or changing the design of the display apparatus. The flexible display apparatus may include a display panel for displaying a screen and a support plate for supporting the display panel. A plurality of slits may be formed in the support plate such that the display panel may be easily folded, bent, or slid.

### SUMMARY

In display apparatuses, a portion of a support plate in which a plurality of slits are formed may not adhere securely to a display panel.

Provided are a display apparatus with improved reliability and a method of manufacturing the same. The embodiments are examples do not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a display panel including a first area, a second area, a folding area between the first area and the second area, and a sliding area across the first area from the folding area, a support plate supporting a lower surface of the display panel and including a first plate portion overlapping the first area, a second plate portion overlapping the second area, a first grid pattern portion overlapping the folding area, and a second grid pattern portion overlapping the sliding area, a main adhesive layer between the display panel and the support plate, and an auxiliary adhesive layer between the main adhesive layer and the support plate and overlapping a portion of the support plate, a plurality of slits in the first grid pattern portion and the second grid pattern portion, wherein the sliding area is slidable in a first direction, and the folding area is foldable with respect to a folding axis extending in a second direction crossing the first direction.

According to one or more embodiments, the auxiliary adhesive layer may include a first auxiliary adhesive layer and a second auxiliary adhesive layer, the first auxiliary adhesive layer may overlap the first grid pattern portion, and the second auxiliary adhesive layer may overlap the second grid pattern portion.

According to one or more embodiments, an adhesive force between the auxiliary adhesive layer and the first and second grid pattern portions may be greater than an adhesive force between the main adhesive layer and the first and second grid pattern portions.

According to one or more embodiments, the main adhesive layer may be a hardened product of a first adhesive layer forming material, the auxiliary adhesive layer may be a hardened product of a second adhesive layer forming material, the first adhesive layer forming material may not include acrylamide, and the second adhesive layer forming material may include acrylamide

According to one or more embodiments, each of the first adhesive layer forming material and the second adhesive layer forming material may include isobornyl acrylate, and the second adhesive layer forming material may include a lower concentration of isobornyl acrylate per unit weight than the first adhesive layer forming material.

According to one or more embodiments, the first grid pattern portion may be in direct contact with the auxiliary adhesive layer and the second grid pattern portion may be in direct contact with the auxiliary adhesive layer.

According to one or more embodiments, the first plate portion may be in direct contact with the main adhesive layer and the second plate portion may be in direct contact with the main adhesive layer.

According to one or more embodiments, the display apparatus may further include a plurality of segments arranged on a lower surface of the second grid pattern portion of the support plate and extending in the second direction while being apart from each other in the first direction, wherein the plurality of segments may include a first segment and a second segment neighboring the first segment, and at least a portion of the first segment and at least a portion of the second segment area may be connected to each other through a link portion therebetween.

According to one or more embodiments, the second grid pattern portion may include a pattern portion in which the plurality of slits are formed and a flat portion in which the plurality of segments are arranged, and the pattern portion and the flat portion may be alternately and arranged.

According to one or more embodiments, the display apparatus may further include a storage container in which the display panel is stored, wherein the storage container may include a first storage container, a second storage container, a hinge arranged between the first storage container and the second storage container, and a third storage container across the first storage container from the hinge, a guide rail may be in the third storage container, the guide rail guiding a movement of the display panel, and the plurality of segments may include a guide area engaged with the guide rail.

According to one or more embodiments, a method of manufacturing a display apparatus may include forming an auxiliary adhesive layer on a second surface of a main adhesive layer opposite to a first surface of the main adhesive layer by using an initiated chemical vapor deposition method, attaching the first surface of the main adhesive layer to a display panel, and attaching the second surface of the main adhesive layer to a support plate, wherein the display panel includes a first area, a second area, a folding area between the first area and the second area, and a sliding area across the first area from the folding area, wherein the sliding area is slidable in a first direction, the folding area is foldable with respect to a folding axis extending in a second direction crossing the first direction, the support plate includes a first plate portion, a second plate portion, a first grid pattern portion, and a second grid pattern portion, a plurality of slits in the first grid pattern portion and the second grid pattern portion, and the attaching of the second surface includes attaching the second surface of the main adhesive layer to the support plate such that the first plate portion overlaps the first area, the second plate portion overlaps the second area, the first grid pattern portion overlaps the folding area, and the second grid pattern portion overlaps the sliding area.

According to one or more embodiments, the auxiliary adhesive layer may include a first auxiliary adhesive layer and a second auxiliary adhesive layer, and the attaching of the second surface may include attaching the second surface of the main adhesive layer to the support plate such that the first auxiliary adhesive layer overlaps the first grid pattern portion and the second auxiliary adhesive layer overlaps the second grid pattern portion.

According to one or more embodiments, an adhesive force between the auxiliary adhesive layer and the first and second grid pattern portions may be greater than an adhesive force between the main adhesive layer and the first and second grid pattern portions.

According to one or more embodiments, the main adhesive layer may be a hardened product of a first adhesive layer forming material not including acrylamide and the forming of the auxiliary adhesive layer may include forming the auxiliary adhesive layer by using a second adhesive layer forming material including acrylamide.

According to one or more embodiments, each of the first adhesive layer forming material and the second adhesive layer forming material may include isobornyl acrylate, and the second adhesive layer forming material may include a lower concentration of isobornyl acrylate per unit weight than the first adhesive layer forming material.

According to one or more embodiments, the attaching of the second surface may include attaching the second surface of the main adhesive layer to the support plate such that the first grid pattern portion is in direct contact with the auxiliary adhesive layer and the second grid pattern portion is in direct contact with the auxiliary adhesive layer.

According to one or more embodiments, the attaching of the second surface may include attaching the second surface of the main adhesive layer to the support plate such that the first plate portion is in direct contact with the main adhesive layer and the second plate portion is in direct contact with the main adhesive layer.

According to one or more embodiments, a method of manufacturing a display apparatus includes forming an auxiliary adhesive layer on a portion of a third surface of a support plate by using an initiated chemical vapor deposition method, attaching a first surface of a main adhesive layer to a display panel, and attaching a second surface of the main adhesive layer, which is an opposite surface to the first surface of the main adhesive layer, to the third surface of the support plate, wherein the display panel includes a first area, a second area, a folding area between the first area and the second area, and a sliding area across the first area from the folding area, wherein the sliding area is slidable in a first direction, and the folding area is foldable with respect to a folding axis extending in a second direction crossing the first direction, the support plate includes a first plate portion, a second plate portion, a first grid pattern portion, and a second grid pattern portion, a plurality of slits in the first grid pattern portion and the second grid pattern portion, and the attaching of the second surface includes attaching the second surface of the main adhesive layer to the support plate such that the first plate portion overlaps the first area, the second plate portion overlaps the second area, the first grid pattern portion overlaps the folding area, and the second grid pattern portion overlaps the sliding area.

According to one or more embodiments, the auxiliary adhesive layer may include a first auxiliary adhesive layer and a second auxiliary adhesive layer, and the forming of the auxiliary adhesive layer may include forming the auxiliary adhesive layer on a portion of the third surface of the support plate such that the first auxiliary adhesive layer is formed on the first grid pattern portion and the second auxiliary adhesive layer is formed on the second grid pattern portion.

According to one or more embodiments, an adhesive force between the auxiliary adhesive layer and the support plate may be greater than an adhesive force between the main adhesive layer and the support plate.

According to one or more embodiments, the main adhesive layer may be a hardened product of a first adhesive layer forming material that is free of acrylamide and the forming of the auxiliary adhesive layer may include forming the auxiliary adhesive layer by using a second adhesive layer forming material including acrylamide.

According to one or more embodiments, each of the first adhesive layer forming material and the second adhesive layer forming material may include isobornyl acrylate, and the second adhesive layer forming material may include a lower concentration of isobornyl acrylate per unit weight than the first adhesive layer forming material.

According to one or more embodiments, the attaching of the second surface may include attaching the second surface of the main adhesive layer to the support plate such that the first grid pattern portion is in direct contact with the auxiliary adhesive layer and the second grid pattern portion is in direct contact with the auxiliary adhesive layer.

According to one or more embodiments, the attaching of the second surface may include attaching the second surface of the main adhesive layer to the support plate.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic perspective view of a display apparatus in a folded state according to an embodiment;

FIG. 3 is a schematic perspective view of a display apparatus in a slid state according to an embodiment;

FIGS. 4 and 5 are schematic perspective views illustrating an arrangement relationship between a display panel and a panel support of the display apparatus according to an embodiment;

FIG. 6 is a schematic cross-sectional view of the display apparatus taken along line X1-X1′ of FIG. 5;

FIG. 7 is a schematic plan view of a panel support of the display apparatus according to an embodiment;

FIG. 8 is a schematic perspective view illustrating an arrangement relationship between a support plate and a segment of the display apparatus according to an embodiment;

FIG. 9 is a schematic perspective view of a panel storage container of the display apparatus according to an embodiment;

FIG. 10 is an exploded perspective view of a panel storage container of the display apparatus according to an embodiment;

FIG. 11 is a schematic perspective view of an arrangement relation between a panel storage container and a segment of the display apparatus;

FIG. 12 is a schematic cross-sectional view of the display apparatus taken along line X2-X2′ of FIG. 11;

FIG. 13 is a perspective view to explain distance changes between a plurality of segments in a panel curve area of the display apparatus according to an embodiment;

FIG. 14 is a perspective view showing adjacent segments of a display apparatus according to an embodiment and a link portion therebetween;

FIGS. 15 to 17 are cross-sectional views schematically illustrating some of the manufacturing process of the display apparatus of FIG. 6; and

FIGS. 18 to 20 are cross-sectional views schematically illustrating some of the manufacturing process of the display apparatus of FIG. 6.

### DETAILED DESCRIPTION

References will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, preferred embodiments are illustrated in the drawings and are described in the detailed description. An effect and a characteristic of the disclosure, and a method of accomplishing these will be apparent when referring to embodiments described with reference to the drawings. The disclosure may, however, be embodied in many different forms and should not be construed as limited to the embodiments set forth herein.

In the specification, the terms “first” and “second” are not used in a limited sense and are used to distinguish one component from another component.

In the specification, an expression used in the singular encompasses the expression of the plural, unless it has a clearly different meaning in the context.

It will be further understood that the terms “comprises” and/or “comprising” used herein specify the presence of stated features or components, but do not preclude the presence or addition of one or more other features or components.

In this specification, the expression “A and/or B” may indicate A, B, or A and B. Also, the expression “at least one of A and B” may indicate A, B, or A and B.

It will be understood that when a component, such as a layer, a film, a region, or a plate, is referred to as being “on” another component, the component may be directly on the other component or intervening components may be present therebetween.

When a layer, region, component, or the like is connected to another layer, region, component, or the like, the layer, the region, the component, or the like may be directly connected thereto and/or may be indirectly connected thereto with an intervening layer, region, component, or the like therebetween. For example, it will be understood in this specification that when an element, an area, or a layer is referred to as being in contact with or being electrically connected to another element, area, or layer, it can be directly and/or indirectly in contact with or electrically connected to the other element, area, or layer.

In the specification, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

When a certain embodiment may be implemented differently, a specific process order may be performed differently from the order in which it is described. For example, two consecutively described processes may be performed substantially at the same time or performed in an order that is reverse of the described order.

Hereinafter, embodiments will be described in detail with reference to the accompanying drawings, wherein the same or corresponding elements are denoted by the same reference numerals throughout and a repeated description thereof is omitted. Sizes of components in the drawings may be exaggerated or otherwise adjusted for convenience of explanation. For example, because sizes and thicknesses of elements in the drawings are arbitrarily illustrated for convenience of explanation, the disclosure is not limited thereto.

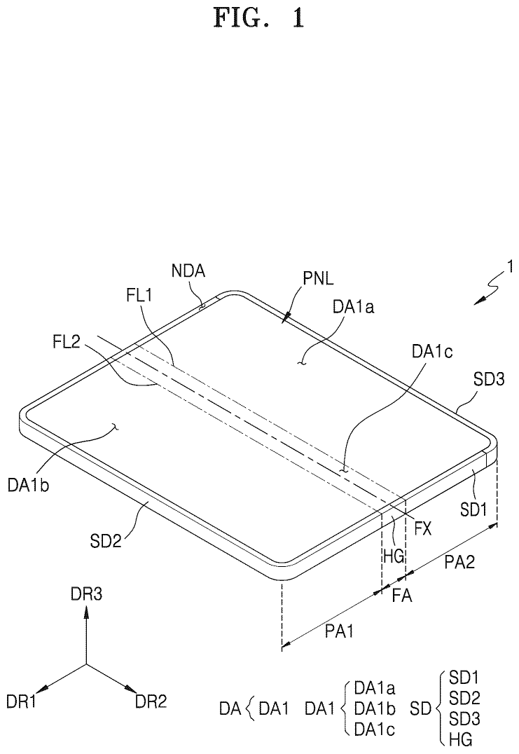

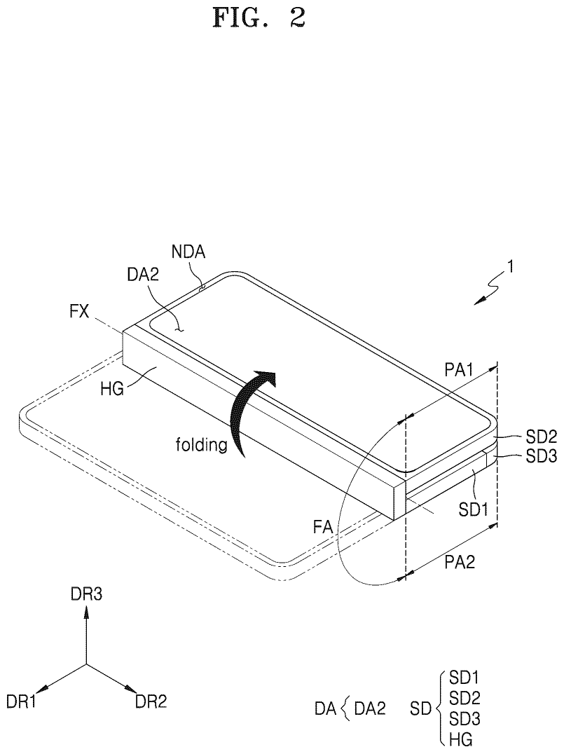

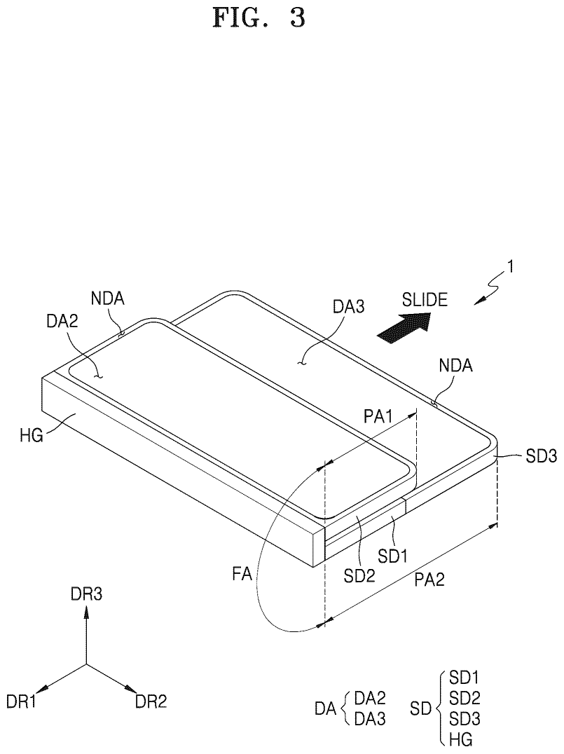

FIG. 1 is a schematic perspective view of a display apparatus 1 according to an embodiment. FIG. 2 is a schematic perspective view of the display apparatus 1 in a folded state according to an embodiment. FIG. 3 is a schematic perspective view of the display apparatus 1 in a slid state according to an embodiment.

In FIG. 1, a first direction DR1, a second direction DR2, and a third direction DR3 are defined. The first direction DR1 may be perpendicular to the second direction DR2 and the third direction DR3 and the second direction DR2 may be perpendicular to the third direction DR3. In the drawing, it may be understood that the first direction DR1 refers to a horizontal direction, the second direction DR2 refers to a vertical direction, and the third direction DR3 refers to upward and downward directions, that is, a thickness direction. Hereinafter, unless mentioned, the “direction” may refer to both directions along a line (i.e., the direction indicated by the arrow in the coordinate system and the opposite direction). If it is necessary to distinguish between the two “directions” along a line, one direction may be referred to as “a positive direction” and the other direction as “the negative direction.” Based on FIG. 1, a direction to which the arrow points is referred to as a positive direction and the opposite direction is referred to as the negative direction.

Referring to FIGS. 1, 2, and 3, the display apparatus 1 displays a video or a still image. The display apparatus 1 may refer to all electronic devices providing a display screen. For example, the display apparatus 1 may include a television, a laptop, a monitor, a billboard, Internet of Things (IoT), a mobile phone, a smartphone, a tablet personal computer (PC), an electronic watch, a smartwatch, a watchphone, a head mount display, a mobile communication terminal, an electronic notebook, an electronic book, a portable multimedia player (PMP), a navigation, a game machine, a digital camera, a camcorder, etc., which provide a display screen.

The display apparatus 1 may include a first flat area PA1, a second flat area PA2, and a folding area FA. The folding area FA may be arranged between the first flat area PA1 and the second flat area PA2 in the first direction DR1. The first flat area PA1 and the second flat area PA2 are areas may not be curved and the folding area FA may be curved. In addition, the second flat area PA2 may expand. The description of the operation of the display apparatus 1 is provided below.

The display apparatus 1 may include a display panel PNL and a panel storage container SD. The panel storage container SD may include a first storage container SD1, a second storage container SD2, and a third storage container SD3. The first storage container SD1 may be arranged on one side of a hinge HG in the first direction DR1, and the second storage container SD2 may be arranged on the other side of the hinge HG. That is, the hinge HG may be arranged between the first storage container SD1 and the second storage container SD2. The third storage container SD3 may be arranged on the side of the first storage container SD1 that is farthest from the hinge HG. That is, the first storage container SD1 may be between third storage container SD3 and the hinge HG in the first direction DR1. The second storage container SD2 may be arranged in the first flat area PA1 of the display apparatus 1, the first storage container SD1 and the third storage container SD3 may be arranged in the second flat area PA2, and the hinge HG may be arranged in the folding area FA.

A display panel PNL is a panel that displays a screen and any display panel such as an organic light-emitting display panel including an organic emission layer, a micro light-emitting diode (LED) display panel using a micro LED, a quantum dot light-emitting display panel using a quantum dot LED, or an inorganic light-emitting display panel using an inorganic LED including an inorganic semiconductor may be applied to the display panel PNL of the present embodiment.

The display panel PNL may be stored in the panel storage container SD, a portion thereof may be exposed from the panel storage container SD, and some of the exposed portions may provide a screen to the user in the third direction DR3 as a display area DA of the display apparatus 1. A non-display area NDA may be arranged around the display area DA. In an embodiment, the non-display area NDA may surround the display area DA, but the disclosure is not limited thereto.

For convenience of explanation, when referring to the surfaces of the display apparatus 1 or of each member included in the display apparatus 1, a direction in which the screen is displayed, that is, a surface facing a side of the third direction of FIG. 1 is referred to as an “upper surface” and a surface opposite to the upper surface is referred to as a “lower surface.” However, the disclosure is not limited thereto and the surface and the other surface of the member may be referred to as a front surface and a back surface, respectively, or may be referred to as a first surface or a second surface. In addition, in describing the relative position of each member of the display apparatus 1, one side of the third direction DR3 may be referred to as an upper portion and the other side of the third direction DR3 may be referred to as a lower portion.

The display apparatus 1 may be a foldable display apparatus. For example, as shown in FIGS. 1 and 2, the display apparatus 1 may be folded with respect to a folding axis FX the folding area FA that extends in the second direction DR2. The folding area FA may be arranged between the first flat area PA1 and the second flat area PA2 and allow the display apparatus 1 to be folded such that the first flat area PA1 overlaps the second flat area PA2.

Referring to FIG. 1, the display apparatus 1 may be unfolded and provide a screen to the user. For example, the display panel PNL may form a first display area DA1 as the display area DA when the display apparatus 1 is unfolded.

The first display area DA1 may include a first flat display area DA1a exposed to the first storage container SD1, a second flat display area DA1b exposed to the second storage container SD2, and a folding display area DA1c exposed to the hinge HG. That is, the first flat display area DA1a may be arranged on one side of the folding display area DA1c and the second flat display area DA1b may be arranged on the other side of the folding display area DA1c.

The folding display area DA1c may be distinguished from the first flat display area DA1a and the second flat display area DA1b with respect to folding lines FL1 and FL2 (hereinafter, also referred to as a first folding line FL1 and a second folding line FL2). For example, the folding display area DA1c and the first flat display area DA1a may be distinguished from each other by the first folding line FL1 acting as a boundary therebetween, and the folding display area DA1c and the second flat display area DA1b may be distinguished from each other by the second folding line FL2 acting as a boundary therebetween.

Referring to FIG. 2, the display apparatus 1 may be folded and provide a screen to the user. In an embodiment, the display panel PNL may form a second display area DA2 as the display region DA when the display apparatus 1 is folded. However, the disclosure is not limited thereto. For example, in some embodiments, the second display area DA2 may not be formed on the lower surface of the first display area DA1. FIG. 2 shows an example where the second display area DA2 may function as the display area DA with the display apparatus 1 in a folded state.

When the display apparatus 1 is in a folded state, the first display area DA1 may not be visible to the user. For example, when the display apparatus 1 is folded, since the first flat display area DA1a and the second flat display area DA1b face each other in the third direction DR3, the first flat display area DA1a may is covered by the second flat display area DA1b and not visible to the user.

The display apparatus 1 may be a slidable display apparatus. For example, as shown in FIG. 3, the display apparatus 1 the third storage container SD3 may slide in and out of the first storage container SD1 in the first direction DR1. With the third storage container SD3 pulled out of the first storage container SD1, the second flat area PA2 of the display apparatus 1 is expanded to an area greater than the first flat area PA1.

In this pulled-out state, the display panel PNL may further include a third display area DA3 as the display area DA. The third display area DA3 is a slidable and may provide a screen to the user when the display apparatus 1 is slid out and expanded. Accordingly, as shown in FIG. 3, the display apparatus 1 may provide a screen to the user not only through the second display area DA2 but also through the third display area DA3. Hereinafter, each structure that forms the display apparatus 1 is described.

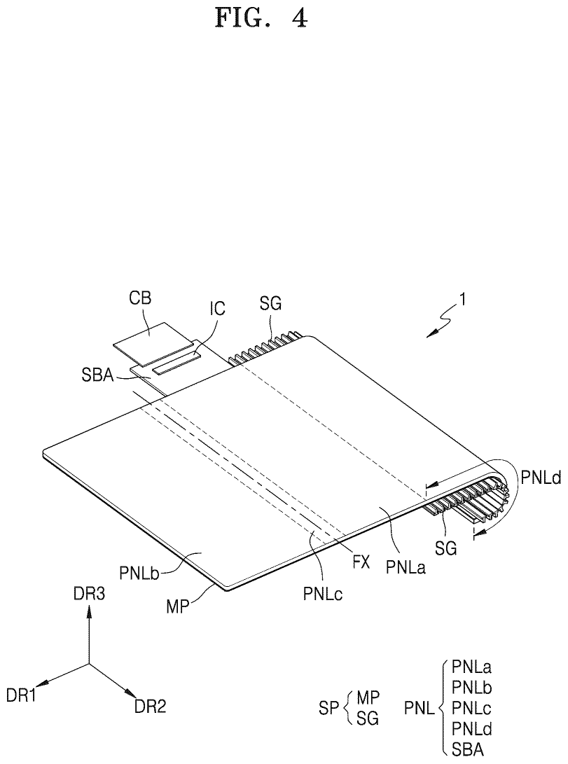

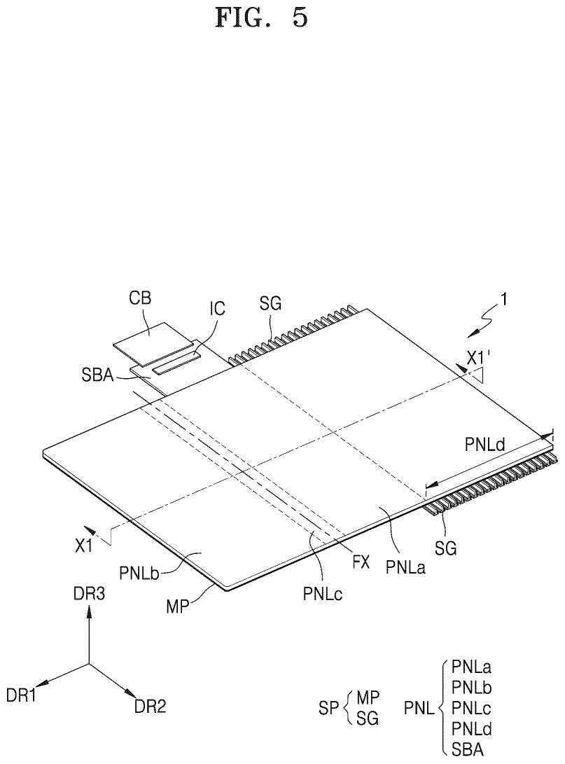

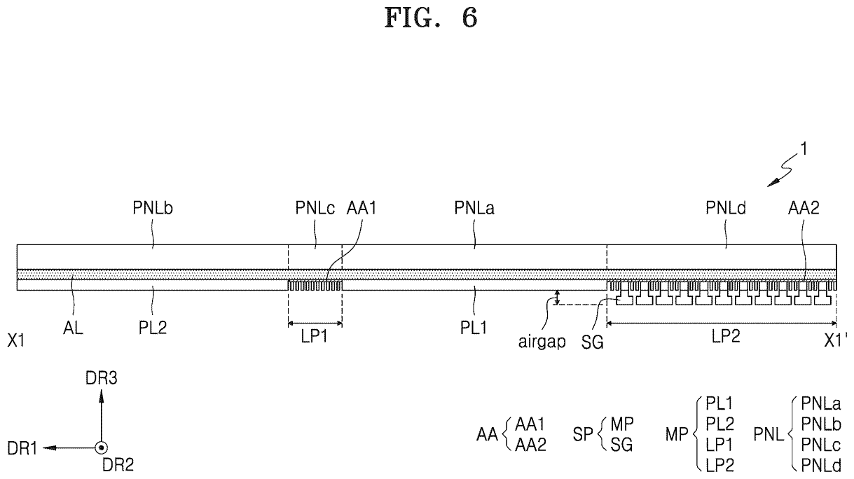

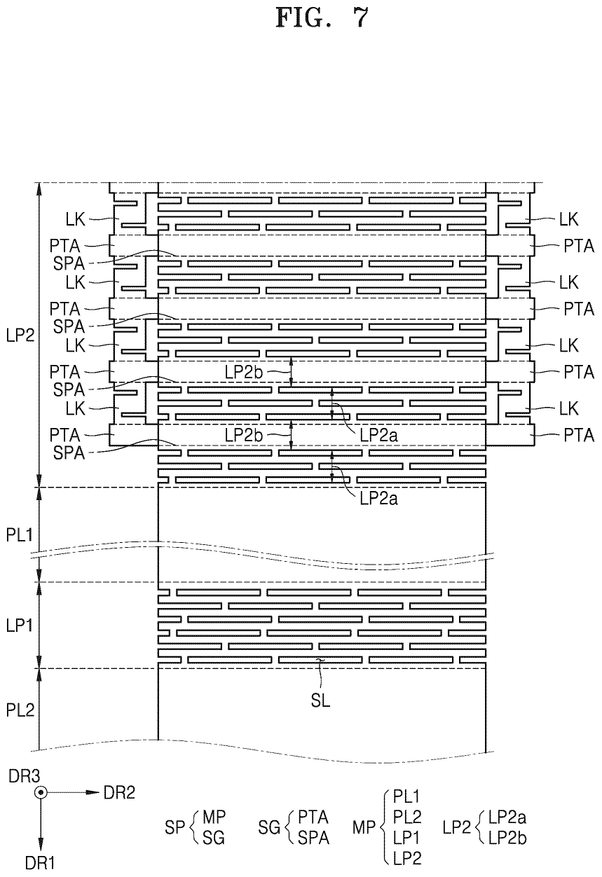

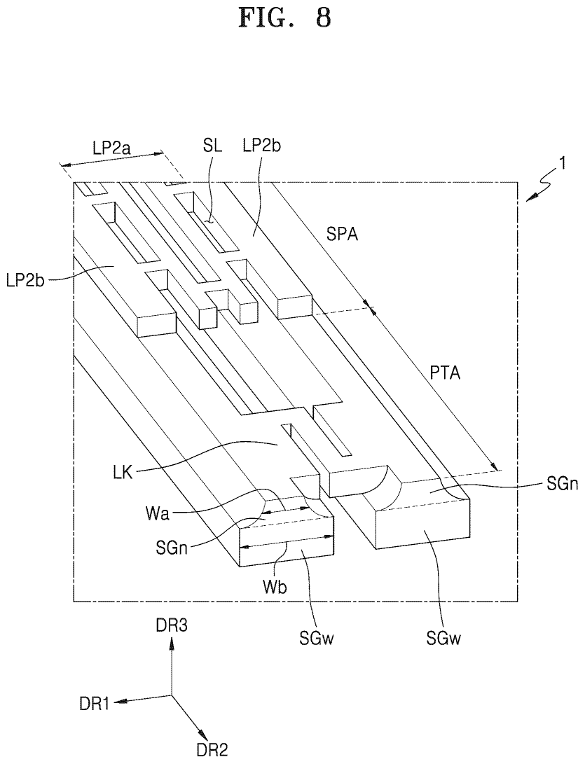

FIGS. 4 and 5 are perspective views schematically illustrating an arrangement relationship between the display panel PNL and the panel support SP of the display apparatus 1 according to an embodiment. Specifically, FIG. 4 illustrates the display panel PNL and the panel support SP in a state in which the display apparatus 1 is partially pulled out and FIG. 5 illustrates the display panel PNL and the panel support SP in a state in which the display apparatus 1 is fully pulled out, according to an embodiment. FIG. 6 is a schematic cross-sectional view of the display apparatus 1 taken along line X1-X1′ of FIG. 5. FIG. 7 is a schematic plan view of the panel support SP of the display apparatus 1 according to an embodiment. FIG. 8 is a schematic perspective view illustrating an arrangement relationship between a support plate MP and a segment SG of the display apparatus 1 according to an embodiment.

Referring to FIGS. 4 to 8, the display apparatus 1 may include the display panel PNL and the panel support SP supporting the bottom of the display panel PNL. The display panel PNL may include a first area PNLa, a second area PNLb, a third area PNLc, a fourth area PNLd, and a sub area SBA.

Referring to FIG. 4 in conjunction with FIGS. 1 to 3, the first area PNLa of the display panel PNL is arranged in the second flat area PA2 of the display apparatus 1 and a portion thereof may be exposed by the first storage container SD1 to form the first flat display area DA1a of the first display area DA1.

The second area PNLb of the display panel PNL is arranged in the first flat area PA1 of the display apparatus 1 and a portion thereof may be exposed by the first second storage container SD2 to form the second flat display area DA1b of the first display area DA1.

The third area PNLc of the display panel PNL is arranged in the folding area FA of the display apparatus 1 and a portion thereof may be exposed by the hinge HG to form the folding display area DA1c of the first display area DA1. That is, the third area PNLc may be arranged between the first area PNLa and the second area PNLb. The third area PNLc may be a curved area. In the claims, the third area PNLc may be referred to as the folding area.

The fourth area PNLd of the display panel PNL is arranged in the second flat area PA2 of the display apparatus 1, and when the display apparatus 1 is pulled out, a portion of the fourth area PNLd may be exposed by the third storage container SD3 to form the third display area DA3. That is, the fourth area PNLd may be arranged opposite to the third area PNLc with the first area PNLa therebetween. The fourth area PNLd is a flexible area that may be slid out while being supported by the structure of the panel support SP and the panel storage container SD described below. Details thereof will be described below. In the claims, the fourth area PNLd may be referred to as the sliding area.

The sub area SBA of the display panel PNL may be a portion protruding to the other side of the second direction DR2 of the first area PNLa. The sub area SBA may be folded, curved, or bent. When the sub area SBA is bent, the sub area SBA may overlap the first area PNLa in the third direction DR3. The sub area SBA may have a flat rectangular form, but the disclosure is not limited thereto.

In an embodiment, a length of the first direction DR1 of the sub area SBA may be less than a length of the first direction DR1 of the first area PNLa, but the disclosure is not limited thereto. For example, the length of the first direction DR1 of the sub area SBA may be substantially the same as the length of the first direction DR1 of the first area PNLa.

A driving circuit IC and a circuit board CB may be arranged on one side of the third direction DR3 of the sub area SBA. The circuit board CB may be attached to the sub area SBA by using an anisotropic conductive film ACF. The circuit board CB may be electrically connected to the pads formed in the sub area SBA. The circuit board CB may be a flexible film such as a flexible printed circuit board, a printed circuit board, or a chip on film. The driving circuit IC may be formed of an integrated circuit and may adhere to the sub area SBA through a chip on glass (COG) method, a chip on plastic (COP) method, or an ultrasound method. Alternatively, the driving circuit IC may adhere to the circuit board CB.

A plurality of pixels may be disposed on the display panel PNL to provide a screen to the user and the panel support SP supporting the display panel PNL may be disposed on the lower surface of the display panel PNL.

Referring to FIGS. 6 to 8, the panel support SP may include the support plate MP and a plurality of segments SG.

The support plate MP of the panel support SP may entirely support the lower surface of the display panel PNL. The support plate MP may include a first plate portion PL1, a second plate portion PL2, a first grid pattern portion LP1, and a second grid pattern portion LP2.

The first plate portion PL1 of the support plate MP may support the lower surface of the first area PNLa of the display panel PNL. In other words, the first plate portion PL1 may overlap the first area PNLa. The first plate portion PL1 has a flat form parallel to a plane defined in the first direction DR1 and the second direction DR2 and may support the first area PNLa such that the first area PNLa is not curved.

The second plate portion PL2 of the support plate MP may support the lower surface of the second area PNLa of the display panel PNL. In other words, the second plate portion PL2 may overlap the second area PNLb. The second plate portion PL2 may be disposed on a side of the first direction DR1 of the first plate portion PL1. The second plate portion PL2 has a flat form parallel to a plane formed by the first direction DR1 and the second direction DR2 and may support the second area PNLb such that the second area PNLb is not curved.

The first grid pattern portion LP1 of the support plate MP may support the lower surface of the third area PNLc of the display panel PNL. In other words, the first grid pattern portion PL1 may overlap the third area PNLc. The first grid pattern portion LP1 may be arranged between the first plate portion PL1 and the second plate portion PL2. In the first grid pattern portion LP1, a plurality of slits SL penetrating through the first grid pattern portion LP1 may be formed. In other words, in the first grid pattern portion LP1, the plurality of slits SL penetrating through the support plate MP may be formed. Accordingly, the lower surface of the third area PNLc may be supported while facilitating the curvature of the third area PNLc of the display panel PNL.

The second grid pattern portion LP2 of the support plate MP may support the lower surface of the fourth area PNLd of the display panel PNL. In other words, the second grid pattern portion LP2 may overlap the fourth area PNLd. The second grid pattern portion LP2 may be arranged on the other side of the first direction DR1 of the first plate portion PL1. That is, the second grid pattern portion LP2 may be disposed in an opposite direction of the first grid pattern portion LP1 with the first plate portion PL1 therebetween. In the second grid pattern portion LP2, a plurality of slits SL penetrating through the second grid pattern portion LP2 may be formed. In other words, in the second grid pattern portion LP2, the plurality of slits SL penetrating through the support plate MP may be formed.

In particular, the second grid pattern portion LP2 may include a pattern portion LP2a and a flat portion LP2b. In the pattern portion LP2a of the second grid pattern portion LP2, the plurality of slits SL penetrating through the second grid pattern portion LP2 may be formed. The segment SG may be attached to the flat portion LP2b. The pattern portion LP2a and the flat portion LP2b may be alternately and repeatedly arranged in the first direction DR1. By the above configuration, the second grid pattern portion LP2 may facilitate a slide operation of the fourth area PNLd of the display panel PNL and also support the lower surface of the fourth area PNLd.

In an embodiment, the support plate MP may include a metal material such as SUS304, but the disclosure is not limited thereto. In an embodiment, the thickness of the support plate MP may be 100 μm or more and or 150 μm or less, but the disclosure is not limited thereto.

The plurality of segments SG may be disposed on the lower surface of the support plate MP. For example, each of the plurality of segments SG may be disposed on the flat portion LP2b of the second grid pattern portion LP2 of the support plate MP as described above. The plurality of segments SG may each extend in the second direction DR2 and be apart from each other in the first direction DR1.

As depicted in FIG. 5, the plurality of segments SG may extend in the second direction DR2 beyond the edges of the support plate MP. In the embodiment of FIG. 5, For example, each of the plurality of segments SG may include a support area SPA overlapping the flat portion LP2b of the second grid pattern portion LP2 of the support plate MP in the third direction DR3 and a protrusion area PTA protruding from the flat portion LP2b in the second direction DR2.

The support area SPA of each of the plurality of segments SG may be attached to the flat portion LP2b of the second grid pattern portion LP2 of the support plate MP and support the lower surface of the fourth area PNLd of the display panel PNL. Unlike the first grid pattern portion LP1, since portions of the second grid pattern portion LP2 being curved may vary according to the slide operation of the display apparatus 1, the mechanical stability of the second grid pattern portion LP2 may be less than that of the first grid pattern portion LP1. Accordingly, the plurality of segments SG may be additionally arranged in the second grid pattern portion LP2 to improve the mechanical stability of the second grid pattern portion LP2.

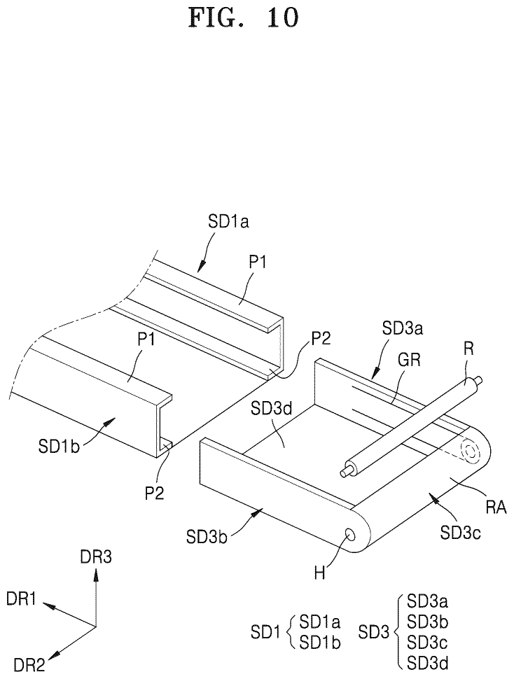

The protrusion area PTA of each of the plurality of segments SG may protrude and be exposed from the second grid pattern portion LP2 of the support plate MP in the second direction DR2. The protrusion area PTA of each of the plurality of segments SG may guide the display panel PNL when it slides in and out, in engagement with the guide rails GR (refer to FIG. 10) formed in the panel storage container SD. Details thereof will be described below. The protrusion area PTA may be referred to as a guide area in the claims.

In addition, the protrusion areas PTA of the plurality of segments SG may be connected to each other through the protrusion areas PTA of adjacent segments SG and the link portion LK. Accordingly, the plurality of segments SG may be prevented from being separated from the display panel PNL by the curve of the display panel PNL. Details thereof will be described below.

In an embodiment, the plurality of segments SG may have a shape in which the width of the upper portion is less than the width of the lower portion, but the disclosure is not limited thereto. For example, the plurality of segments SG may have a shape in which the width narrows toward the lower portion.

FIGS. 6 and 8 show examples of the plurality of segments SG having a shape in which the width of the upper portion is less than the width of the lower portion, that is, a convex ( ) shape. In this case, the plurality of segments SG may include an attachment portion SGn attached to the support plate MP and a body portion SGw disposed on the lower portion of the attachment portion SGn. The attachment portion SGn of each of the plurality of segments SG may be welded to the flat portion LP2b of the support plate MP, but the disclosure is not limited thereto. For example, a separate attachment member arranged between the attachment portion SGn and the flat portion LP2b may attach the attachment portion SGn to the flat portion LP2b.

The adhesive portion SGn protrudes from the body portion SGw and may have a width WA in the first direction DR1 narrower than that of the body portion SGw in first direction DR1. Accordingly, the plurality of segments SG may relatively reduce the area of the plurality of segments SG attached to the support plate MP and expand an area of the pattern portion LP2a of the second grid pattern portion LP2 to facilitate the curvature of the display panel PNL, and, since the stiffness of the segment SG itself is obtained through the body portion SGw, the plurality of segments SG may be prevented from being bent in the area where the display panel PNL is curved. Details thereof will be described below.

In an embodiment, the plurality of segments SG may include metal materials such as SUS 304. In addition, in an embodiment, each width Wb of each of the plurality of segments SG may be about 0.4 mm or more and about 1.3 mm or less. However, the disclosure is not limited thereto.

As described above, the link portion LK may connect the protrusion area PTA of adjacent segments SG among the plurality of segments SG. In an embodiment, the link portion LK may be integrally formed with the attachment portion SGn of each adjacent segment SG to connect the adjacent segments SG to each other, but the disclosure is not limited thereto. When the link portion LK is formed integrally with the plurality of segments SG, the link portion LK may be formed simultaneously with the segment SG without the need for a separate process of forming the link portion LK in the process of forming the plurality of segments SG, and thus, there is an advantage in the manufacturing process, and since a separate attachment member is not needed, a mechanical stability of the link portion LK itself may be secured.

As shown in FIG. 6, an air gap may be formed on the side of the first plate portion PL1 that does not contact the main adhesive layer AL. The air gap may be formed on the lower portion of the first plate portion PL1, thereby relieving an impact applied to the display panel PNL. For example, the air gap may absorb an impact caused by an object such as a pen falling on the first area PNLa of the display panel PNL.

On the other hand, referring to FIG. 6, the display apparatus 1 may include a main adhesive layer AL and an auxiliary adhesive layer AA.

The main adhesive layer AL may be arranged between the display panel PNL and the support plate MP. The main adhesive layer AL may attach the support plate MP to the display panel PNL. In other words, the main adhesive layer AL may attach the panel support SP to the display panel PNL. In particular, a surface of the main adhesive layer AL may be attached to a front surface of the display panel PNL and the other surface of the main adhesive layer AL may be attached to the support plate MP and the auxiliary adhesive layer AA on the support plate MP such that the main adhesive layer AL may attach the support plate MP to the display panel PNL. In other words, an upper surface of the main adhesive layer AL may be in contact with the display panel PNL. The auxiliary adhesive layer AA may be arranged in a portion of the lower surface of the main adhesive layer AL, which is an opposite surface of the upper surface of the main adhesive layer AL, and a portion of the lower surface of the main adhesive layer AL and the auxiliary adhesive layer AA may be in contact with the support plate MP.

The main adhesive layer AL may include at least one of a pressure sensitive adhesive (PSA) and an optical clear adhesive (OCA). In particular, the main adhesive layer AL may be a hardened product of a first adhesive layer forming material. That is, the first adhesive layer forming material may include monomers and may form the main adhesive layer AL by polymerizing the monomers. For example, the first adhesive layer forming material may include 2-ethylhexyl acrylate, acrylic acid, isobornyl acrylate, methylacrylate, and 2-hydroxyethyl acrylate. On the other hand, the first adhesive layer forming material may further include an initiator. For example, the initiator may be Irgacure 184™. The Irgacure 184™ may be 1-hydroxycyclohexyl benzophenone.

The auxiliary adhesive layer AL may be arranged between the main adhesive layer AL and the support plate MP. The auxiliary adhesive layer AA may overlap a portion of the support plate MP. In particular, the auxiliary adhesive layer AA may include a first auxiliary adhesive layer AA1 and a second auxiliary adhesive layer AA2. The first auxiliary adhesive layer AA1 may be arranged between a portion of the main adhesive layer AL disposed under the third area PNLc of the display panel PNL and the first grid pattern portion LP1 and the second auxiliary adhesive layer AA2 may be arranged between a portion of the main adhesive layer AL disposed under the fourth area PNLd of the display panel PNL and the second grid pattern portion LP2. That is, the first grid pattern portion LP1 may be attached to the third area PNLc through a portion of the main adhesive layer AL and the first auxiliary adhesive layer AA1, which are disposed under the third area PNLc. Similarly, the first second pattern portion LP2 may be attached to the fourth area PNLd through a portion of the main adhesive layer AL and the second auxiliary adhesive layer AA2, which are disposed under the fourth area PNLd.

The auxiliary adhesive layer AA may not be disposed under a portion of the main adhesive layer AL disposed under the first area PNLa and may not be disposed under a portion of the main adhesive layer AL disposed under the second area PNLb. In other words, the auxiliary adhesive layer AA may not be disposed on the first plate portion PL1 and the second plate portion PL2. Accordingly, the first plate portion PL1 may be attached to the first area PNLa through the main adhesive layer AL and the second plate portion PL2 may be attached to the second area PNLb through the main adhesive layer AL. That is, the first plate portion PL1 may be in direct contact with the main adhesive layer AL and the second plate portion PL2 may be in direct contact with the main adhesive layer AL. The first grid pattern portion LP1 may be in direct contact with the auxiliary adhesive layer AA and the second grid pattern portion LP2 may be in direct contact with the auxiliary adhesive layer AA.

An adhesive force between the auxiliary adhesive layer AA and the support plate may be greater than that between the main adhesive layer AL and the support plate. To this end, the auxiliary adhesive layer AA may be a hardened product of the second adhesive layer forming material further including acrylamide. That is, the second adhesive layer forming material may include monomers and may form the auxiliary adhesive layer AA by polymerizing the monomers. In particular, like the first adhesive layer forming material, the second adhesive layer forming material may further include 2-ethylhexyl acrylate (2-EHA), acrylic acid, isobornyl acrylate, methylacrylate, and 2-hydroxyethyl acrylate, and the second adhesive layer forming material may further include acrylamide. The second adhesive layer forming material may also further include an initiator. For example, the initiator may be Irgacure 184™. The Irgacure 184™ may be 1-hydroxycyclohexyl benzophenone.

Acrylamide may improve the adhesion of the adhesive layer to the support plate. The adhesive layer forms material includes acrylamide is hardened to form the adhesive layer. Since the second adhesive layer forming material further includes acrylamide, the auxiliary adhesive layer AA may have a higher adhesive force than the main adhesive layer A1.

In general, when the plurality of slits SL are formed in the first grid pattern portion LP1, a contact area between the first grid pattern portion LP1 and the layer disposed on the first grid pattern portion LP1 may be less than when the plurality of slits SL are not formed in the first grid pattern portion LP1. Therefore, since the adhesive force between the first grid pattern portion LP1 and the layer disposed on the first grid pattern portion LP1 is low, the first grid pattern portion LP1 may be easily detached from the layer disposed on the first grid pattern portion LP1. Similarly, when the plurality of slits SL are formed in the second grid pattern portion LP2, a contact area between the second grid pattern portion LP2 and the layer disposed on the second grid pattern portion LP2 may be less than when the plurality of slits SL are not formed in the second grid pattern portion LP2. Therefore, since the adhesive force between the second grid pattern portion LP2 and the layer disposed on the second grid pattern portion LP2 is low, the second grid pattern portion LP2 may be easily detached from the layer disposed on the second grid pattern portion LP2.

However, in the display apparatus 1 according to the present embodiment, the plurality of slit SLs may be continuously formed in the first grid pattern portion LP1 and the second grid pattern portion LP2, a portion of the auxiliary adhesive layer AA may be arranged between the first grid pattern portion LP1 and a portion of the main adhesive layer AL disposed on the first grid pattern portion LP1, and the other portion of the auxiliary adhesive layer AA may be arranged between the second grid pattern portion LP2 and a portion of the main adhesive layer AL disposed on the second grid pattern portion LP2. That is, the first auxiliary adhesive layer AA1 may be arranged between a portion of the main adhesive layer AL disposed under the third area PNLc and the second auxiliary adhesive layer AA2 may be arranged between a portion of the main adhesive layer AL disposed under the fourth area PNLd and the second grid pattern portion LP2. Therefore, the adhesive force between the first grid pattern portion LP1 and the layer disposed on the first grid pattern portion LP1 and the adhesive force between the second grid pattern portion LP2 and the layer disposed on the second grid pattern portion LP2 may be improved. Thus, the reliability of the display apparatus 1 may be improved.

As the second adhesive layer forming material further includes acrylamide, a ratio of monomers other than acrylamide in the second adhesive layer may be reduced. For example, the second adhesive layer forming material may include a lower ratio of isobornyl acrylate than the first adhesive layer forming material. That is, the first adhesive layer forming material may include isobornyl acrylate of 15 wt % or more and 20 wt % or less with respect to the total weight of the first adhesive layer forming material. The second adhesive layer forming material may include isobornyl acrylate of less than 10 wt % with respect to the total weight of the second adhesive layer forming material. In other words, the first adhesive layer forming material may include a higher concentration of isobornyl acrylate per unit weight than the second adhesive layer forming material.

Isobornyl acrylate may improve impact resistance of an adhesive layer of which the forming material including isobornyl acrylate is hardened. Since the first adhesive layer forming material includes a higher concentration of isobornyl acrylate, the main adhesive layer AL may have a higher impact resistance than the auxiliary adhesive layer AA.

In general, when the display apparatus is folded or slid, a slip phenomenon in which adjacent layers stacked with adhesive layers therebetween are slipped along the surface may occur. For example, the display panel may be attached to another layer of the display apparatus by the adhesive layer, and, as the display panel is slid along the surface, the display apparatus may be folded or slid. In this case, when the adhesive force of the adhesive layer is too high, the slip phenomenon may be difficult to occur, and accordingly, the display apparatus may not be easily folded or slid.

However, in the display apparatus 1 according to the present embodiment, the auxiliary adhesive layer AA may be arranged between the display panel PNL and the support plate MP and the auxiliary adhesive layer AA may not be arranged between a portion of the main adhesive layer AL disposed under the first area PNLa and the first plate portion PL1, and between a portion of the main adhesive layer AL disposed under the second area PNLb and the second plate portion PL2. That is, the first plate portion PL1 may be attached to the first area PNLa through the main adhesive layer AL and the second plate portion PL2 may be attached to the second area PNLb through the main adhesive layer AL. Accordingly, since the adhesive force between the display panel PNL and the support plate MP is not too high, the slip phenomenon may easily occur. Accordingly, the display apparatus 1 may be easily folded or slid.

A thickness of the auxiliary adhesive layer AA may be less than that of the main adhesive layer AL. For example, the thickness of the main adhesive layer AL may be 50 μm and the thickness of the auxiliary adhesive layer AA may be 20 μm. Hereinafter, a structure in which the panel storage container SD and the segment SG may be engaged with each other to guide a slide operation of the display panel PNL will be described.

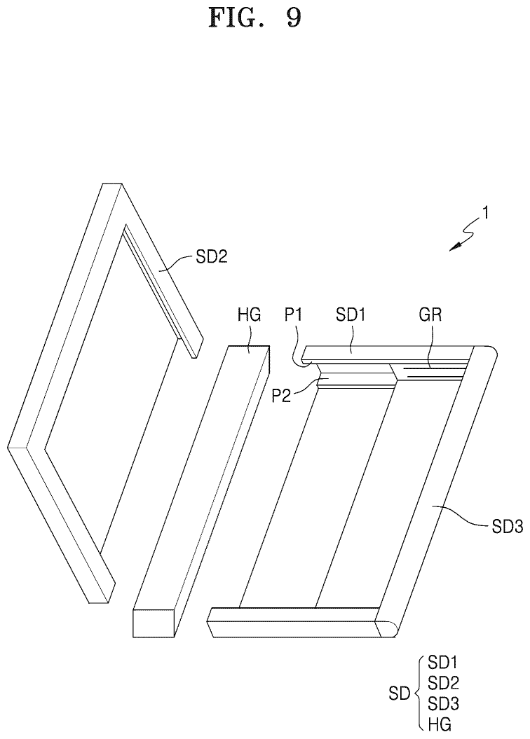

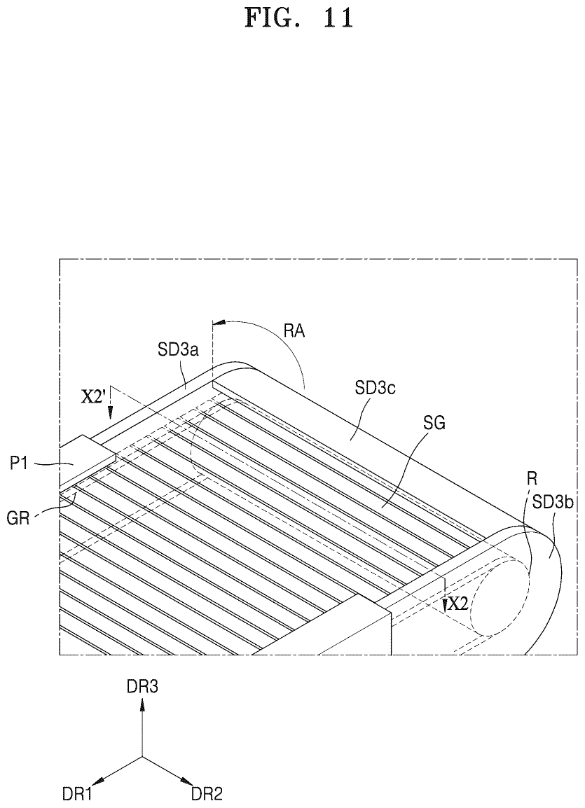

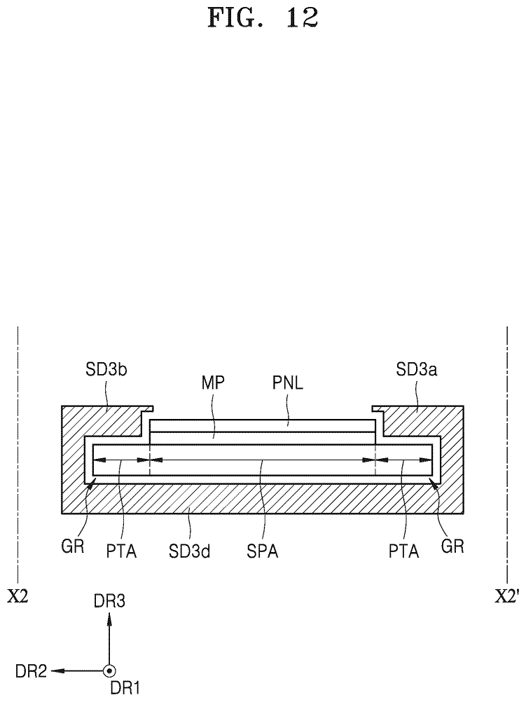

FIG. 9 is a schematic perspective view of the panel storage container SD of the display apparatus 1 according to an embodiment. FIG. 10 is an exploded perspective view of the panel storage container SD of the display apparatus 1 according to an embodiment. FIG. 11 is a schematic perspective view of an arrangement relation between the panel storage container SD and the segment SG of the display apparatus 1. FIG. 12 is a schematic cross-sectional view of the display apparatus 1 taken along line X2-X2′ of FIG. 11. In FIG. 12, the illustration of the adhesive layers is omitted for convenience.

Referring to FIGS. 9 to 12, the panel storage container SD of the display apparatus 1 according to an embodiment may include a first storage container SD1, a second storage container SD2, a third storage container SD3, and a hinge HG.

Referring to FIG. 9 in conjunction with FIGS. 1 and 2, the hinge HG may be arranged between the first storage container SD1 and the second storage container SD2 such that the first storage container SD1 and the second storage container SD2 may pivot around the hinge HG.

Accordingly, the display apparatus 1, as a foldable display apparatus, may be folded by the hinge HG such that the first storage container SD1 faces the second storage container SD2.

Referring to FIGS. 2 and 3 in conjunction with FIG. 9, the third storage container SD3 may be slid from the first storage container SD1. For example, the third storage container SD3 may be engaged with and slid between the fixing portions P1 and P2 formed in the first storage container SD1. A guide rail GR to guide the slide operation of the display panel PNL may be formed in the third storage container SD3.

Referring to FIG. 10, in the arrangement relation between the first storage container SD1 and the third storage container SD3, the first storage container SD1 may include a first side wall portion SD1a on the other side of the second direction DR2 and a second side wall portion SD1b on a side of the second direction DR2 and an area exposing a portion of the display panel PNL may be formed between the first side wall portion SD1a and the second side wall portion SD1b. A fixing portion protruding in the second direction DR2, that is, toward the inside of the first storage container SD1, may be formed at both ends of the third direction DR3 of each of the first side wall portion SD1a and the second side wall portion SD1b. In other words, a first fixing portion P1 may be formed at one end of the third direction DR3 of each of the first side wall portion SD1a and the second side wall portion SD1b and a second fixing portion P2 may be formed at the other end of the third direction DR3 of each of the first side wall portion SD1a and the second side wall portion SD1b. The first fixing portion P1 and the second fixing portion P2 may face each other in the third direction DR3. Accordingly, the third storage container SD3 may be engaged with and slid in a space formed between the first fixing portion P1 and the second fixing portion P2.

Referring to FIG. 10, the third storage container SD3 may include slide portions at both sides of the second direction DR2. In particular, the third storage container SD3 may include a first slide portion SD3a of the other side of the second direction DR2 and a second slide portion SD3b of one side of the second direction DR2. The slide portion may have a flat form having a plane defined in the first direction DR1 and the third direction DR3. The slide portion may be engaged with and slid in the first direction DR1 between the first fixing portion P1 and the second fixing portion P2 formed on each of the first side wall portion SD1a and the second side wall portion SD1b of the first storage container SD1.

In the first slide portion SD3a and the second slide portion SD3b of the third storage container SD3, the guide rail GR engaged with the protrusion area PTA of the plurality of segments SG of the panel support SP may be formed. The guide rail GR may define a trajectory along which the display panel PNL is slid. As shown in FIG. 12, the guide rail GR is a groove in each of the first slide portion SD3a and the second slide portion SD3b and may be engaged with the protrusion area PTA of each of the plurality of segments SG. In this case, the support area SPA of each of the plurality of segments SG may overlap the support plate MP and the display panel PNL disposed on the support plate MP in the third direction DR3.

The third storage container SD3 may further include a cover portion SD3c connecting the other end of the first direction DR1 of the first slide portion SD3a to the other end of the second slide portion SD3b. As shown in FIG. 10, a curve area RA at which the display panel PNL is curved may be formed in the cover portion SD3c.

In an embodiment, the guide rail GR may have a U-shape rotated counterclockwise by 90 degrees. In other words, the guide rail GR may extend on one side of the first direction DR1, curve on the other side of the third direction DR3 in the panel curve area RA, and extend on the other side of the first direction DR1. In an area of the slide portion in which an interval wherein the guide rail GR is curved is formed, a hole H for arranging the roll R described below may be formed.

The panel storage container SD may further include a roll R (see FIG. 10). The roll R may assist the slide behavior of the display panel PNL. The roll R may have a cylindrical shape with a circular cross-section. The roll R may be inserted into and fixed in the hole H formed in the slide portion and may rotate as the display panel PNL slides in and out.

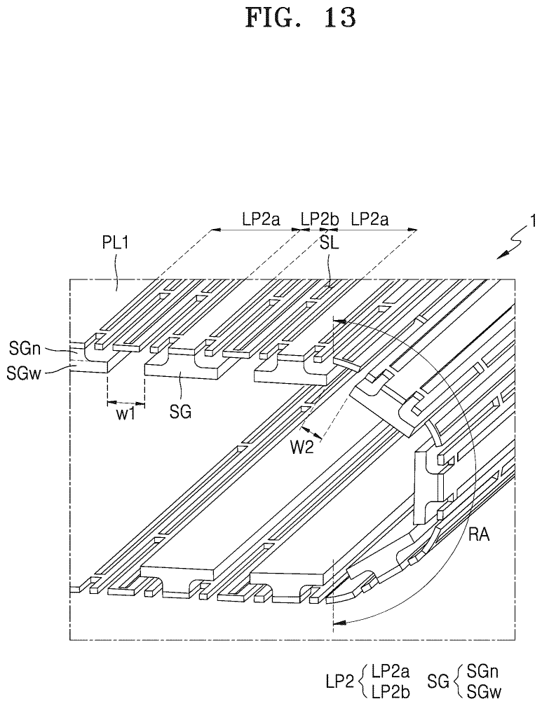

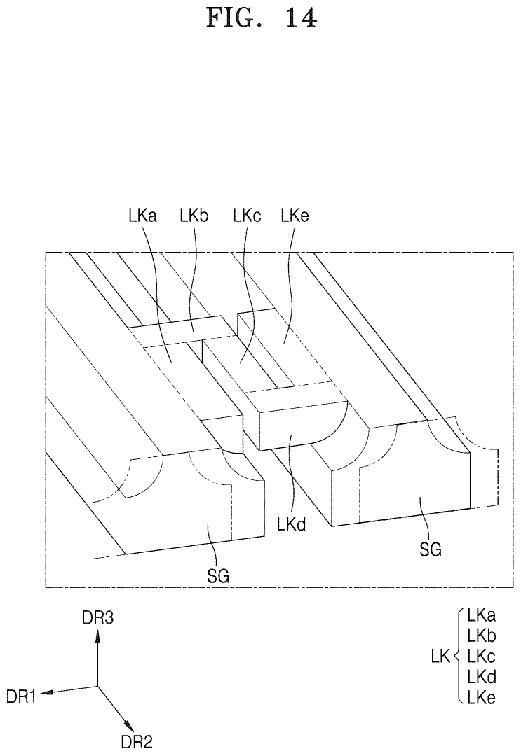

FIG. 13 is a perspective view to explain distance changes between the plurality of segments SG in the panel curve area RA of the display apparatus 1 according to an embodiment. FIG. 14 is a perspective view showing adjacent segments of the display apparatus 1 according to an embodiment and the link portion therebetween. In FIG. 13, for convenience, illustrations of the roll R, the panel storage container SD, and the link portion LK are omitted.

Referring to FIG. 13 in conjunction with FIGS. 9 to 12, since the plurality of segments SG are engaged with the guide rail GR, the plurality of segments SG may be arranged along the guide rail GR curved in the panel curve area RA and, accordingly, the support plate MP and the display panel PNL disposed on the plurality of segments SG may also be curved in the panel curve area RA. In this case, the distance between the adjacent segments SG may have a first width w1 in a flat area, but may have a width w2 less than the first width w1 in the panel curve area RA. In other words, distances between adjacent segments SG in the panel curve area RA and in a flat area may be different.

However, when the distance between the adjacent segments SG in the panel curve area RA is decreased more than necessary, stress may be applied to the attachment portion SGn between the support plate MP and the attachment portion SGn of the segment SG, thereby causing the segment SG to be separated from the segment MP. Therefore, it is necessary to maintain some distance between the plurality of segments SG in the panel curve area RA to prevent the segment SG from being separated.

Referring to FIG. 14, the link portion LK of the display apparatus 1 according to an embodiment is disposed between the adjacent segments SG and formed integrally with each segment SG such that the distance between the plurality of segments SG are maintained in the panel curve area RA as well.

The link portion LK of the display apparatus 1 may have an N or a Z shape. For example, referring to FIG. 14, a “first segment” and a “second segment” are shown with the link portion LK arranged between the first segment and the second segment. The first segment and the second segment may be arranged in an alternating manner along the first direction DR1. The link portion LK may include a first portion LKa formed integrally with the first segment and extending in the second direction DR2, a fifth portion LKe formed integrally with the second segment and extending in the second direction DR2, and a third portion LKc between the first portion LKa and the second portion LKb, spaced apart from the first portion LKa and the second portion LKb and extending in the second direction DR2. A second portion LKb extends between a first end of the first portion LKa and a closest end of the third portion LKc, and extends in the first direction DR1. A fourth portion LKd extends between a first end of the third portion LKc and a closest end of the fifth portion and extends in the first direction DR1.

When the distance between the adjacent segments SG is decreased, a the first portion LKa and the third portion LKc of the link portion LK may become closer to each other, and the fifth portion LKd and the third portion LKc may become closer, thereby allowing the link portion LK to have a predetermined resilience, that is, elastic force. Accordingly, even when the distance between the plurality of segments SGs is decreased in the panel curve area RA, the distance is secured by the elasticity of the link portion LK, thereby preventing the segment SG from being separated.

In addition, the connecting part LK may prevent the plurality of segments SG from being deformed as the display panel PNL is curved in the panel curve area RA. For example, the display panel PNL may be curved in the panel curve area RA and the plurality of segments SG supporting the area in which the display panel PNL is curved may be transformed, such as being twisted, rotated, compressed, or tensed according to the curve of the display panel PNL. Since the link portion LK fixes both ends of the plurality of segments SG supporting the area in which the display panel PNL is curved in the panel curve area RA, the plurality of segments SG may be prevented from being transformed as described above.

In an embodiment, the link portion LK may be formed integrally with the plurality of segments SG. For example, the link portion LK may be formed integrally with the plurality of segments SG without a separate adhesive member, thereby including the same material (e.g., a metal material such as SUS304). Accordingly, the link portion LK may be formed in the same manufacturing process as the plurality of segments SG without going through a separate manufacturing process.

So far, the display apparatus 1 has been described, but the disclosure is not limited thereto. The method of manufacturing the display apparatus 1 also falls within the scope of the disclosure. Hereinafter, the method of manufacturing the display apparatus 1 is described.

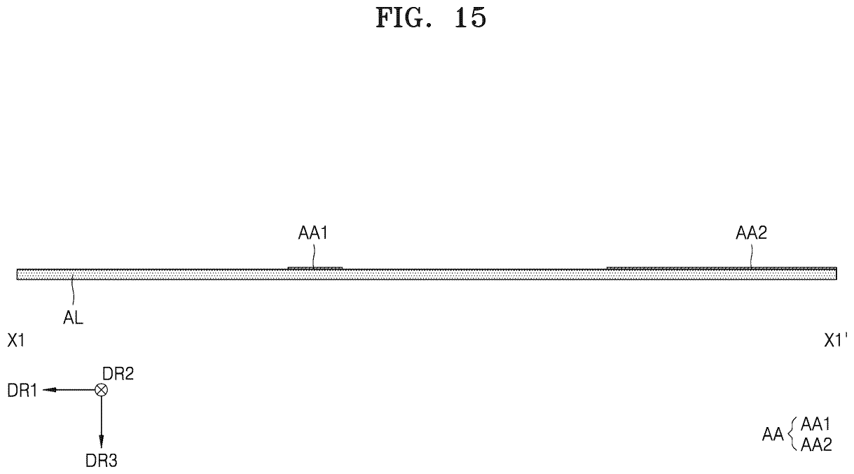

FIGS. 15 to 17 are cross-sectional views schematically illustrating some of the manufacturing process of the display apparatus 1 of FIG. 6. In particular, FIGS. 15 to 17 are cross-sectional views schematically illustrating the process of attaching the panel support SP to the display panel PNL. In FIGS. 15 to 17, for convenience of explanation, the method of manufacturing the display apparatus 1 is described based on a cross-section of the display apparatus 1 taken along line X1-X1′ of FIG. 5. Hereinafter, in explaining the method of manufacturing the display apparatus 1 according to an embodiment with reference to FIGS. 15 to 17, since the reference numerals of FIGS. 15 to 17 that are the same as those of FIGS. 1 to 14 denote the same members, redundant descriptions thereof will be omitted.

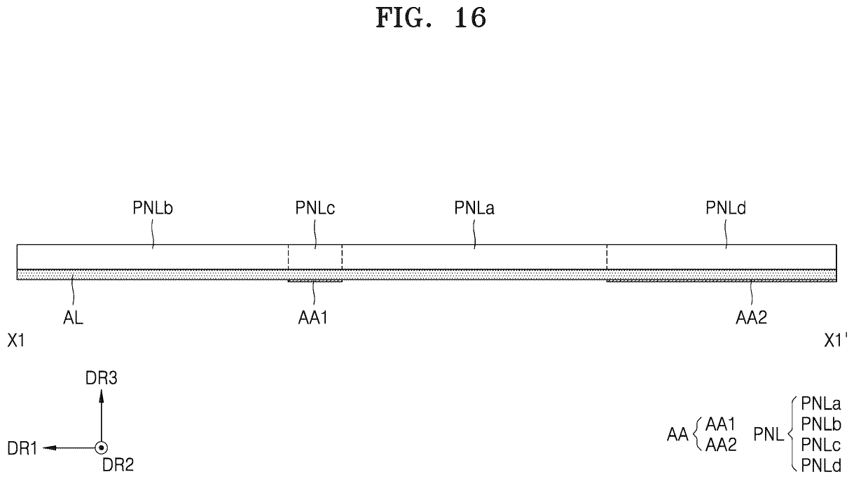

First, referring to FIG. 15, auxiliary adhesive layer AA may be formed on the main adhesive layer AL. In particular, the auxiliary adhesive layer AA may be formed on a portion of the lower surface (e.g., a second surface) of the main adhesive layer AL opposite to the upper surface (e.g., a first surface) of the main adhesive layer AL. As described above with reference to FIG. 6, since the upper surface of the main adhesive layer AL may be in contact with the display panel PNL and the auxiliary adhesive layer AA may be disposed on a portion of the lower surface of the main adhesive layer AL that is opposite to the upper surface of the main adhesive layer AL, FIG. 15 depicts the main adhesive layer AL in an upside down state such that the lower surface of the main adhesive layer AL of FIGS. 6 and 16 faces upwards.

The auxiliary adhesive layer AA may be formed using an initiated chemical vapor deposition (iCVD) method. The iCVD method is one of the chemical vapor deposition methods and may be based on a chain polymerization using free radicals. The iCVD method may refer to a process of depositing a polymer thin film on a surface of a substrate by causing a polymer reaction by vaporizing monomers and initiators. When simply mixing the initiator and the monomer, polymerization may not occur, but when the initiator is decomposed by a high temperature (e.g., more than 180° C.) heating wire (e.g., a filament) arranged in the chamber and a radical is generated, monomers may be activated, thereby causing a chain polymerization reaction. By leaving a substrate on which a polymer thin film is deposited for a certain time (e.g., 48 hours) in a chamber having a predetermined temperature (e.g., 90° C.), the polymer forming the polymer thin film may further be hardened, and accordingly, the molecular weight of the polymer may be increased. When forming the polymer thin film by using the iCVD method, a more uniform polymer thin film may be formed compared to other methods for forming the polymer thin film (e.g., inkjet printing).

In particular, the iCVD method may be used for the synthesis of homogeneous random copolymers. For example, polymerization using hydrophobic monomer and hydrophilic monomer, which is impossible in liquid state, may be performed in a gas state. The iCVD method may uniformly form a single film on a substrate with irregular shapes, such as fibers. In addition, when the temperature of the heating wire in the chamber is about 200° C., the polymer may be deposited on the substrate in a state in which the polymerization is not terminated, and, in this case, polymerization may be in progress even after the deposition. In particular, the auxiliary adhesive layer may be formed by using the second adhesive layer forming material. That is, the auxiliary adhesive layer AA may be deposited on the lower surface of the main adhesive layer AL by causing polymer reaction by vaporizing the second adhesive layer forming material. The second adhesive layer forming material may include monomers and initiators. For example, the second adhesive layer forming material may include 2-ethylhexyl acrylate, acrylic acid, isobornyl acrylate, methylacrylate, 2-hydroxyethyl acrylate, and acrylamide. The second adhesive layer forming material may further include an Irgacure 184™. The Irgacure 184™ may be 1-hydroxycyclohexyl benzophenone.

The auxiliary adhesive layer AA may include the first auxiliary adhesive layer AA1 and the second auxiliary adhesive layer AA2. The first auxiliary adhesive layer AA1 and the second auxiliary adhesive layer AA2 may be apart from each other in the first direction DR1 and formed on the main adhesive layer AL. That is, when forming the auxiliary adhesive layer AA on the main adhesive layer AL, the auxiliary adhesive layer AA may be formed only on a portion of the main adhesive layer AL by using a mask. In other words, by using the iCVD method, the auxiliary adhesive layer AA including the first auxiliary adhesive layer AA1 and the second auxiliary adhesive layer AA2 apart from each other in the first direction DR1 may be formed on the main adhesive layer AL. The iCVD method and the method of using the mask is a general content in the formation of a polymer thin film, so details thereof are omitted.

The main adhesive layer AL may be a hardened product of the first adhesive layer. The hardened product of the first adhesive layer forming material that results in the first adhesive layer may not include acrylamide. For example, the first adhesive layer forming material may include 2-ethylhexyl acrylate, acrylic acid, isobornyl acrylate, methylacrylate, and 2-hydroxyethyl acrylate and may not include acrylamide. Accordingly, the adhesive force of the auxiliary adhesive layer AA to the support plate may be greater than that of the main adhesive layer AL. Each of the first adhesive layer forming material and the second adhesive layer forming material may include isobornyl acrylate. The first adhesive layer forming material may include a higher concentration of isobornyl acrylate than the second adhesive layer forming material per unit weight. In other words, the second adhesive layer forming material may include a lower concentration of isobornyl acrylate than the first adhesive layer forming material per unit weight.

Referring to FIG. 16, the upper surface of the main adhesive layer AL may be attached to the display panel PNL. As described above, the display panel PNL may include the first area PNLa, the second area PNLb, the third area PNLc between the first area PNLa and the second area PNLb, and the fourth area PNLd opposite to the third area PNLc with the first area PNLa therebetween. The fourth area PNLd may be slid in the first direction DR1 and the third region PNLc may be folded with respect to the folding axis FX extending in the second direction DR2 crossing the first direction DR1. As the upper surface of the main adhesive layer AL is attached to the display panel PNL, the first auxiliary adhesive layer AA1 may overlap the third area PNLc and the second auxiliary adhesive layer AA2 may overlap the fourth area PNLd.

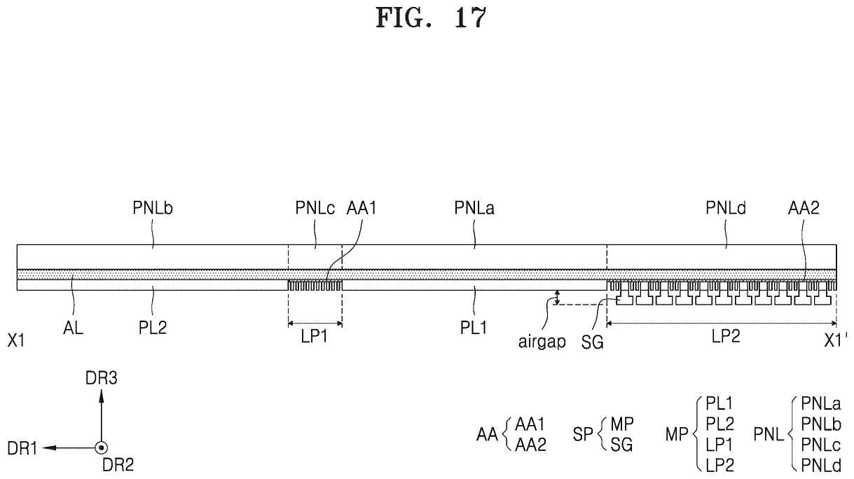

Referring to FIG. 17, the lower surface of the main adhesive layer AL may be attached to the support plate MP. As described above, the support plate MP may include the first plate portion PL1, the second plate portion PL2, the first grid pattern portion LP1, and the second grid pattern portion LP2. The plurality of slits SL may be through-holes extending through the first grid pattern portion LP1 and through the second grid pattern portion LP2. As the lower surface of the main adhesive layer AL is attached to the support plate MP, the first plate portion PL1 may overlap the first area PNLa, the second plate portion PL2 may overlap the second area PNLb, the first grid pattern portion LP1 may overlap the third area PNLc, and the second grid pattern portion LP2 may overlap the fourth area PNLd. In addition, as the lower surface of the main adhesive layer AL is attached to the support plate MP, the first auxiliary adhesive layer AA1 may overlap the first grid pattern portion LP1 and the second auxiliary adhesive layer AA2 may overlap the second grid pattern portion LP2.

Accordingly, the first grid pattern portion LP1 may be in direct contact with the auxiliary adhesive layer AA and the second grid pattern portion LP2 may be in direct contact with the auxiliary adhesive layer AA. The first plate portion PL1 may be in direct contact with the main adhesive layer AL and the second plate portion PL2 may be in direct contact with the main adhesive layer AL. As described above, a plurality of segments SG may be attached to the lower surface of the support plate MP, in particular, the lower surface of the second plate portion PL2.

So far, manufacturing the display apparatus 1 by forming the auxiliary adhesive layer AA on the main adhesive layer AL has been described, but the disclosure is not limited thereto. For example, by forming the auxiliary adhesive layer AA on the support plate MP, the display apparatus 1 may be manufactured. Hereinafter, a method of manufacturing the display apparatus 1 by forming the auxiliary adhesive layer AA on the support plate MP will be described.

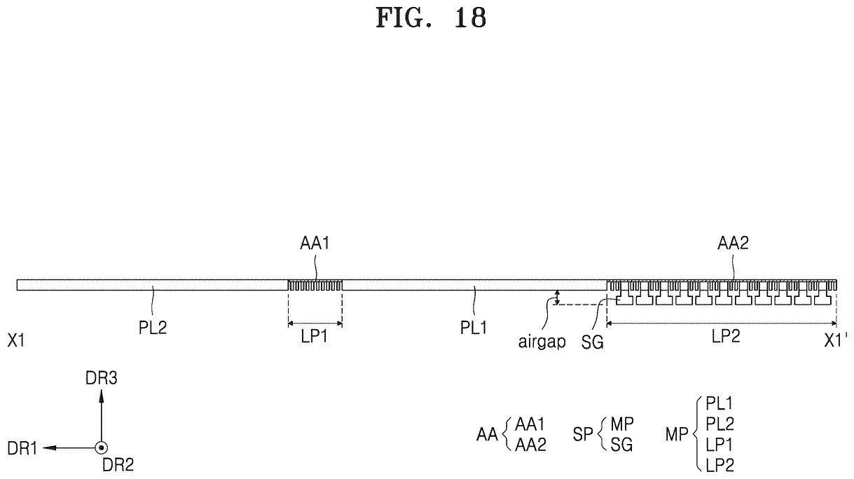

FIGS. 18 to 20 are cross-sectional views schematically illustrating some of the manufacturing process of the display apparatus 1 of FIG. 6. In particular, FIGS. 18 to 20 are cross-sectional views schematically illustrating the process of attaching the panel support SP to the display panel PNL. In FIGS. 18 to 20, for convenience of explanation, the method of manufacturing the display apparatus 1 is described based on a cross-section of the display apparatus 1 taken along line X1-X1′ of FIG. 5. Hereinafter, in explaining the method of manufacturing the display apparatus 1 according to an embodiment with reference to FIGS. 18 to 20, since the reference numerals of FIGS. 18 to 20 that are the same as those of FIGS. 1 to 17 denote the same members, redundant descriptions thereof will be omitted.

First, referring to FIG. 18, the auxiliary adhesive layer AA may be formed on the support plate MP. In particular, the auxiliary adhesive layer AA may be formed on a portion of the upper surface (e.g., a third surface) of the support plate MP, on the first grid pattern portion LP1 and the second grid pattern portion LP2. The auxiliary adhesive layer AA may be formed using an initiated chemical vapor deposition (iCVD) method. In addition, the auxiliary adhesive layer AA including the first auxiliary adhesive layer AA1 and a second auxiliary adhesive layer AA2 that are apart from each other in the first direction DR1 may be formed on the main adhesive layer AL by using the mask. Using the iCVD method or the method of using the mask when forming the auxiliary adhesive layer AA on the main adhesive layer AL described above may be applied to the iCVD method and the method of using the mask when forming the auxiliary adhesive layer AA on the support plate MP. Therefore, redundant descriptions thereof are omitted.

As described above, the support plate MP may include the first plate portion PL1, the second plate portion PL2, the first grid pattern portion LP1, and the second grid pattern portion LP2. The plurality of slits SL in the first grid pattern portion LP1 may be through-holes extending through the thickness of the first grid pattern portion LP1, and the plurality of slits SL in the second grid pattern portion LP2 may be through-holes extending through the thickness of the second grid pattern portion LP2. The first auxiliary adhesive layer AA1 of the auxiliary adhesive layer AA may be formed on the upper surface of the first grid pattern portion LP1, and the second auxiliary adhesive layer AA2 of the auxiliary adhesive layer AA may be formed on the upper surface of the second grid pattern portion LP2. That is, the first auxiliary adhesive layer AA1 may overlap the first grid pattern portion LP1 and the second auxiliary adhesive layer AA2 may overlap the second grid pattern portion LP2.

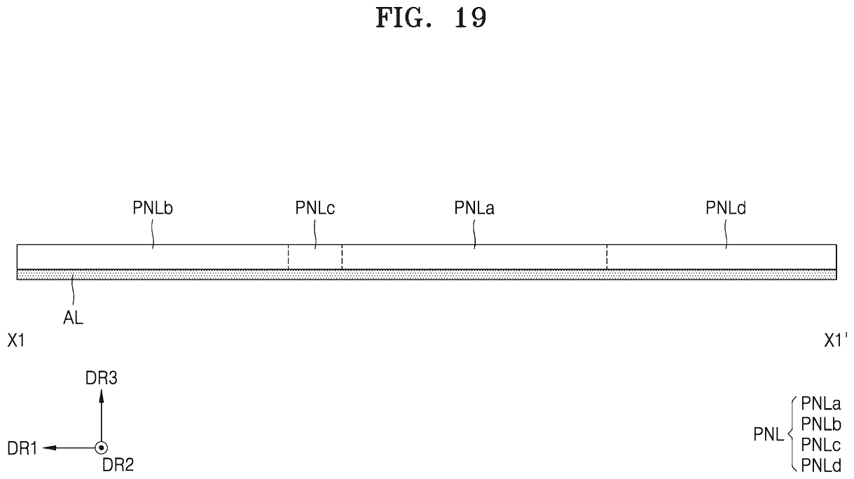

Referring to FIG. 19, the upper surface of the main adhesive layer AL may be attached to the display panel PNL. As described above, the display panel PNL may include the first area PNLa, the second area PNLb, the third area PNLc between the first area PNLa and the second area PNLb, and the fourth area PNLd opposite to the third area PNLc with the first area PNLa therebetween. The fourth area PNLd may be slid in the first direction DR1 and the third region PNLc may be folded with respect to the folding axis FX extending in the second direction DR2 crossing the first direction DR1.

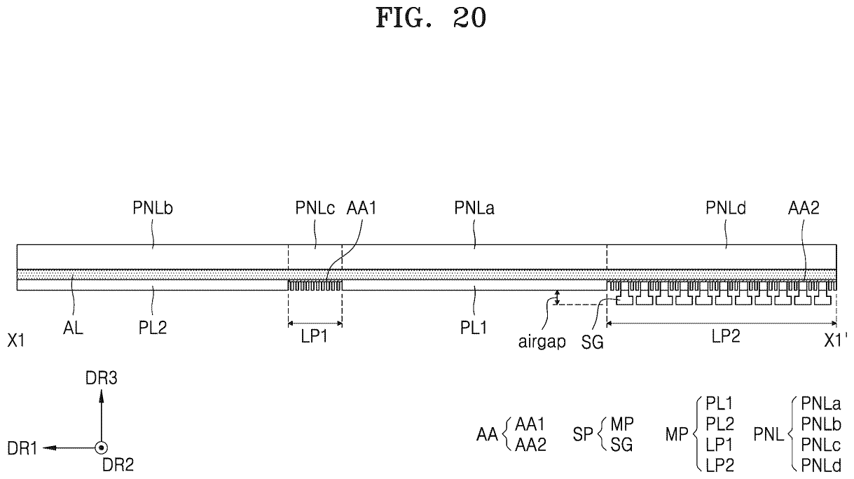

Referring to FIG. 20, the lower surface of the main adhesive layer AL may be attached to the upper surface of the support plate MP. As the lower surface of the main adhesive layer AL is attached to the support plate MP, the first plate portion PL1 may overlap the first area PNLa, the second plate portion PL2 may overlap the second area PNLb, the first grid pattern portion LP1 may overlap the third area PNLc, and the second grid pattern portion LP2 may overlap the fourth area PNLd. Accordingly, the first plate portion PL1 may be in direct contact with the main adhesive layer AL and the second plate portion PL2 may be in direct contact with the main adhesive layer AL. The first grid pattern portion LP1 may be in direct contact with the auxiliary adhesive layer AA and the second grid pattern portion LP2 may be in direct contact with the auxiliary adhesive layer AA.

According to the embodiments, a display apparatus with improved reliability and a method of manufacturing the same may be implemented. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a first area, a second area, a folding area between the first area and the second area, and a sliding area across the first area from the folding area;
a support plate supporting a lower surface of the display panel and comprising a first plate portion overlapping the first area, a second plate portion overlapping the second area, a first grid pattern portion overlapping the folding area, and a second grid pattern portion overlapping the sliding area;
a main adhesive layer between the display panel and the support plate; and
an auxiliary adhesive layer between the main adhesive layer and the support plate and overlapping a portion of the support plate,
a plurality of slits in the first grid pattern portion,
and the second grid pattern portion, wherein
the sliding area is slidable in a first direction, and
the folding area is foldable with respect to a folding axis extending in a second direction crossing the first direction.

2. The display apparatus of claim 1, wherein
the auxiliary adhesive layer comprises a first auxiliary adhesive layer and a second auxiliary adhesive layer,
the first auxiliary adhesive layer overlaps the first grid pattern portion, and
the second auxiliary adhesive layer overlaps the second grid pattern portion.

3. The display apparatus of claim 1, wherein an adhesive force between the auxiliary adhesive layer and the first and second grid pattern portions is greater than an adhesive force between the main adhesive layer and the layers in the first and second grid pattern portions.

4. The display apparatus of claim 3, wherein
the main adhesive layer is a hardened product of a first adhesive layer forming material,
the auxiliary adhesive layer is a hardened product of a second adhesive layer forming material,
the first adhesive layer forming material does not comprise acrylamide, and
the second adhesive layer forming material comprises acrylamide.

5. The display apparatus of claim 4, wherein
each of the first adhesive layer forming material and the second adhesive layer forming material comprises isobornyl acrylate, and
the second adhesive layer forming material comprises a lower concentration of isobornyl acrylate per unit weight than the first adhesive layer forming material.

6. The display apparatus of claim 1, wherein
the first grid pattern portion is in direct contact with the auxiliary adhesive layer, and
the second grid pattern portion is in direct contact with the auxiliary adhesive layer.

7. The display apparatus of claim 6, wherein
the first plate portion is in direct contact with the main adhesive layer, and
the second plate portion is in direct contact with the main adhesive layer.

8. The display apparatus of claim 1, further comprising:
a plurality of segments arranged on a lower surface of the second grid pattern portion of the support plate and extending in the second direction while being apart from each other in the first direction, wherein
the plurality of segments comprise a first segment and a second segment neighboring the first segment, and
at least a portion of the first segment and at least a portion of the second segment area are connected to each other through a link portion therebetween.

9. The display apparatus of claim 8, wherein
the second grid pattern portion comprises a pattern portion in which the plurality of slits are formed and a flat portion in which the plurality of segments are arranged, and
the pattern portion and the flat portion are alternately arranged.

10. The display apparatus of claim 8, further comprising a storage container in which the display panel is stored, wherein
the storage container comprises a first storage container, a second storage container, a hinge arranged between the first storage container and the second storage container, and a third storage container across the first storage container from the hinge,
a guide rail in the third storage container, the guide rail guiding a movement of the display panel, and
the plurality of segments comprise a guide area engaged with the guide rail.

11. A method of manufacturing a display apparatus, the method comprising:
forming an auxiliary adhesive layer on a second surface of a main adhesive layer opposite to a first surface of the main adhesive layer by using an initiated chemical vapor deposition method;
attaching the first surface of the main adhesive layer to a display panel; and
attaching the second surface of the main adhesive layer to a support plate, wherein
the display panel comprises a first area, a second area, a folding area between the first area and the second area, and a sliding area across the first area from the folding area, wherein
the sliding area is slidable in a first direction,
the folding area is foldable with respect to a folding axis extending in a second direction crossing the first direction,
the support plate comprises a first plate portion, a second plate portion, a first grid pattern portion, and a second grid pattern portion,
a plurality of slits in the first grid pattern portion
and the second grid pattern portion, and
the attaching of the second surface comprises attaching the second surface of the main adhesive layer to the support plate such that the first plate portion overlaps the first area, the second plate portion overlaps the second area, the first grid pattern portion overlaps the folding area, and the second grid pattern portion overlaps the sliding area.

12. The method of claim 11, wherein
the auxiliary adhesive layer comprises a first auxiliary adhesive layer and a second auxiliary adhesive layer, and
the attaching of the second surface comprises attaching the second surface of the main adhesive layer to the support plate such that the first auxiliary adhesive layer overlaps the first grid pattern portion and the second auxiliary adhesive layer overlaps the second grid pattern portion.

13. The method of claim 11, wherein an adhesive force between the auxiliary adhesive layer and the first and second grid pattern portions is greater than an adhesive force between the main adhesive layer and the first and second grid pattern portions.

14. The method of claim 11, wherein
the main adhesive layer is a hardened product of a first adhesive layer forming material not comprising acrylamide, and
the forming of the auxiliary adhesive layer comprises forming the auxiliary adhesive layer by using a second adhesive layer forming material comprising acrylamide.

15. The method of claim 14, wherein
each of the first adhesive layer forming material and the second adhesive layer forming material comprises isobornyl acrylate, and
the second adhesive layer forming material comprises a lower concentration of isobornyl acrylate per unit weight than the first adhesive layer forming material.

16. The method of claim 11, wherein the attaching of the second surface comprises attaching the second surface of the main adhesive layer to the support plate such that the first grid pattern portion is in direct contact with the auxiliary adhesive layer and the second grid pattern portion is in direct contact with the auxiliary adhesive layer.

17. The method of claim 16, wherein the attaching of the second surface comprises attaching the second surface of the main adhesive layer to the support plate such that the first plate portion is in direct contact with the main adhesive layer and the second plate portion is in direct contact with the main adhesive layer.

18. A method of manufacturing a display apparatus, the method comprising:
forming an auxiliary adhesive layer on a portion of a third surface of a support plate by using an initiated chemical vapor deposition method;
attaching a first surface of a main adhesive layer to a display panel; and
attaching a second surface of the main adhesive layer, which is an opposite surface to the first surface of the main adhesive layer, to the third surface of the support plate, wherein
the display panel comprises a first area, a second area, a folding area between the first area and the second area, and a sliding area across the first area from the folding area, wherein
the sliding area is slidable in a first direction, and
the folding area is foldable with respect to a folding axis extending in a second direction crossing the first direction,
the support plate comprises a first plate portion, a second plate portion, a first grid pattern portion, and a second grid pattern portion,
a plurality of slits in the first grid pattern portion
and the second grid pattern portion, and
the attaching of the second surface comprises attaching the second surface of the main adhesive layer to the support plate such that the first plate portion overlaps the first area, the second plate portion overlaps the second area, the first grid pattern portion overlaps the folding area, and the second grid pattern portion overlaps the sliding area.

19. The method of claim 18, wherein
the auxiliary adhesive layer comprises a first auxiliary adhesive layer and a second auxiliary adhesive layer, and
the forming of the auxiliary adhesive layer comprises forming the auxiliary adhesive layer on a portion of the third surface of the support plate such that the first auxiliary adhesive layer is formed on the first grid pattern portion and the second auxiliary adhesive layer is formed on the second grid pattern portion.

20. The method of claim 18, wherein an adhesive force between the auxiliary adhesive layer and the support plate is greater than an adhesive force between the main adhesive layer and the support plate.

21. The method of claim 18, wherein
the main adhesive layer is a hardened product of a first adhesive layer forming material that is free of acrylamide, and
the forming of the auxiliary adhesive layer comprises forming the auxiliary adhesive layer by using a second adhesive layer forming material comprising acrylamide.

22. The method of claim 21, wherein
each of the first adhesive layer forming material and the second adhesive layer forming material comprises isobornyl acrylate, and
the second adhesive layer forming material comprises a lower concentration of isobornyl acrylate per unit weight than the first adhesive layer forming material.

23. The method of claim 18, wherein the attaching of the second surface comprises attaching the second surface of the main adhesive layer to the support plate.

24. The method of claim 23, wherein the attaching of the second surface comprises attaching the second surface of the main adhesive layer to the support plate such that the first plate portion is in direct contact with the main adhesive layer and the second plate portion is in direct contact with the main adhesive layer.
